(19) United States
(12) Patent Application Publication
(10) Pub. No.: US 2012/0102854 A1
(43) Pub. Date: May 3, 2012

(54) Assembly for Fastening a Plurality of Solar Modules to a Building Roof or a Building Facade and Clip for Forming a Stop Element on a Surface

(75) Inventors: Christian Meier, Zurich (CH); Eric Langenskiöld, Stafa (CH)

(73) Assignee: ENERGIEBURO AG, Zurich (CH)

(21) Appl. No.: 13/259,806

(22) PCT Filed: Mar. 27, 2009
(86) PCT No.: PCT/CH2009/000104

§ 371 Date: Dec. 19, 2011

(51) Int. Cl. E04D 13/18; B23P 11/00; F16B 2/20; H01L 31/048

(52) U.S. Cl. 52/173.3; 136/251; 29/428; 24/457

(57) ABSTRACT

The invention relates to a fastening assembly for solar modules (1), wherein the solar modules (1) are fastened to carrier profiles (2) arranged in several rows by way of clamping elements (3, 4) in that each clamping element (3, 4) extends over the mutually opposing delimiting edges of two solar modules (2), which run transversely to the carrier profile (2) and adjoin the clamping element (3, 4) on both sides. Each clamping element (3, 4) comprises a ridge element (3) and a head element (4) designed separate therefrom. The ridge element (3) is designed as a profile section and attached at the lower end thereof to the carrier profile (2) through insertion into profile contours of the carrier profile. The head element (4) is attached to the ridge element (3) in the region of the upper end of said element by being inserted into profile contours of the ridge element (3). To this end, the head element (3) protrudes beyond the ridge element (3) on both sides in the profile longitudinal direction of the ridge element (3) so as to extend over the delimiting edges of the solar modules (1) to be fastened. The invention provides a fastening system which comprises few components (2, 3, 4) that can be produced cost-effectively and enables the simple and secure fastening of solar modules (1) even under difficult ambient conditions by using delimiting edges that run transversely to the carrier profiles (2).

### BACKGROUND

The invention is related to an assembly for fastening a plurality of solar modules for assembling a solar array on a building, to a clip for forming a stop element on an outer surface of an even, thin-walled plate-shaped component by fastening the latter in an opening arranged in this outer surface as well as a method for forming a stop element on an even outer surface of a thin-walled component by using the clip according to the preambles of the independent claims.

### PRIOR ART

Different fastening systems have been known for attaching solar modules (also referred to as solar elements) on building roofs in order to assemble solar arrays.

In case of the first emerging fastening systems, the solar modules were screwed by means of fastening clips or fastening angles formed on them directly onto the installation surface or onto a subordinate construction created on the installation surface, this being a relatively work intense and at least a dangerous action on steep roofs, because it required a repeated handling of the cumbersome and at the same time fragile solar modules.

In order to avoid the disadvantages mentioned above, it was proceeded to arrange carrier profiles in parallel rows onto the installation surface and to fasten the individual solar modules onto the carrier profiles by means of clamping profile pieces which are anchored in the carrier profiles by fastening screws with sliding blocks. However, this fastening system has the disadvantage that a plurality of individual components is necessary, resulting in the fact that the installation is exacerbated in practical use. Additionally, in case of this fastening system, the disadvantage arises that the delimiting edges of the solar modules are clamped between the carrier profiles and the clamping profiles in order to fasten the solar modules, such that a thermal expansion of the solar modules is hindered and it may come to a detaching of the fastenings or to a “migration” of the solar modules in the fastenings respectively, as a result of thermal stress.

DE 20 2007 016 011 U1 describes a support device for solar modules of a solar array, for which a plurality of carrier profiles are arranged spacedly from each other in multiple rows and parallel to the eaves on a building roof. The carrier profiles carry multiple clamping elements arranged in a longitudinally displaceable way, which are hinged from above into the carrier profiles. The clamping elements overlap each the delimiting edges of two neighbouring solar modules which extend longitudinally with respect to the particular carrier profile and lie on it. The solar modules are thereby secured against take-off from the respective carrier profile. The clamping elements are each formed by a ridge element attached to the carrier profile by hinging and by a head element which is inserted into the ridge element in the direction of the carrier profile, such that for the installation, first the solar module can be arranged between the ridge elements attached to two neighbouring carrier profiles and after that the head element can be inserted into the ridge elements and secured by means of a securing screw. In case of this fastening system a handling of the solar modules is only needed for inserting them, this significantly reducing the installation effort as well as the danger of damage of the solar modules or of a work accident. A fastening of the solar modules onto the carrier profiles with delimiting edges running transversely with respect to the carrier profiles, as it may for example be desirable in case of steep roofs in order to be able to grant a stable fastening of the solar modules in an upright format, such that an assembly of the photovoltaically inactive connection section of the solar modules in the main fouling zone at its bottom edge running parallel to the eaves becomes possible, is however not possible with this system.

A fastening system similar to the one presented in DE 20 2007 016 011 U1 is offered by the company MONTAVENT GMBH in Zurich, Switzerland, going by the name “montavent”. Here, the carrier profiles and the clamping elements are however formed in such a way that the clamping elements have to be inserted into profile contours of the carrier profiles in longitudinal direction with respect to the carrier profiles. In order to enable a fastening of the solar modules onto the carrier profiles with delimiting edges running transversely with respect to the carrier profiles, helping elements are additionally provided for this system, which can be inserted into the ridge elements of the clamping elements and after that enable a fastening of the clamping elements into the carrier profiles in a position rotated by 90°. By this system a fastening of the solar modules onto the carrier profiles is possible with delimiting edges either running along or transversely with respect to the carrier profiles, however wherein in the latter case additional helping elements are required, this making the installation and the logistics more difficult and moreover creating additional material costs.

Stop elements serve to form a form fit between two bodies which are otherwise movable in abutting direction relatively to each other and are for example attached to the underside of the solar modules for the installation of solar modules onto steep roofs, in order to avoid a slipping in the direction of the eaves. In this case, the stop element abuts for example at a profile section on which the respective solar module lies.

For forming a stop element on an outer surface of an even, thin-walled, plate-shaped component, like for example the underside of the frame of a solar module, it is known how to attach rivets or screws in an opening in the outer surface or how to attach stop bodies like sheet metal angles or ashlar-shaped or cylindrical bodies by means of screws or rivets or by means of material engagement methods like welding, soldering or gluing onto the surface. If a stop element shall be formed in the area of an edge of an outer surface, it is additionally known how to arrange a key-ring-shaped element into an opening in the outer surface in a way such that the area of the component which is located between the opening and the edge is arranged inside the ring.

This last named embodiment however has the disadvantage that the stop element can only be formed in the edge area of an even, thin-walled, plate-shaped component. The embodiments named beforehand, in case of which rivets or screws are used as stop elements or for attaching stop elements, have the disadvantage that the fastening opening in the component and the dimensions of the rivet or of the screw have to be adjusted to one another in a pretty exact way in order to assure a secure fastening. The fastening of stop elements by means of material engaging fastening methods has on the other hand the disadvantage that it requires special method steps and ambient conditions which cannot or can only be carried out or assured respectively, with high effort, particularly in case of mounting larger parts outside, like for example solar modules onto the roof of a building. A further disadvantage of the mentioned stop elements is that they cannot be removed or cannot be removed easily, with the exception of embodiments using screws. In order to assemble or remove stop elements with screw fastening, tools like screwdrivers or screw-wrenches are additionally needed, this making the handling in difficult installation situations, i.e. on a building roof, more difficult and making a one-hand installation or disassembly respectively, impossible. A further disadvantage results for embodiments with machine screws, in that both sides of the fastening opening have to be accessible in order to place the screw nut onto the screw and to be able to hold it during fastening or loosening.

### DISCLOSURE OF THE INVENTION

Because of this, the task arises to provide an assembly for fastening a plurality of solar modules onto a building roof which does not have the disadvantages of the prior art or at least avoids them to an extent or which at least present an alternative to the known fastening systems.

Furthermore, the task is to provide a stop element which does not have the disadvantages of the prior art or which at least avoid them to some extent. Particularly, the stop element shall be such that in can be attached equally in difficult assembly conditions without additional helping means with one hand only at an arbitrary position in an opening in an outer surface of an even, thin-walled, plate-shaped component and to be tolerant with respect to the dimensioning of the opening. It shall also be removable again without needing tools.

The first task is solved by the assembly according to claim 1.

The second mentioned task is solved by the clip according to claim 27 and the method according to claim 41.

According to this, a first aspect of the invention is related to an assembly for the fastening of a plurality of solar modules on a building roof or a building façade for building a solar array on the roof or at the façade. This assembly comprises a plurality of carrier profiles which are arranged in rows spaced from each other and which each carry one or more clamping elements by means of which the solar modules can be held on the carrier profiles. It is provided that the carrier profile rows are each formed by continuous carrier profiles or each one out of a plurality of carrier profile pieces which are spaced with respect to each other. According to this, in the following the term “carrier profile” is understood as continuous carrier profiles as well as single carrier profile pieces if there is no explicit differentiation. The carrier profiles can be attached directly on the roof surface or façade surface or also on subordinate constructions arranged thereon.

The clamping elements are formed in such a way that with each clamping element two neighbouring solar modules can be attached on the carrier profile supporting the clamping element in such a way that the delimiting edges of these solar modules which adjoin the clamping element on both sides and lie on the carrier profile, facing each other and running transversely to the carrier profile are overlapped by the clamping element and are therefore secured in a form fitting way against take-off from the carrier profile.

Each one of the clamping elements comprises a ridge element and a head element which is formed separately from the ridge element, wherein the head element serves for overlapping the delimiting edges of the solar modules and the ridge element is arranged between the delimiting edges of the solar modules and forms the connection between the carrier profile and the head element.

The ridge elements are formed as profile sections and are form fittingly attached to the corresponding carrier profile at their lower ends, each being oriented with the longitudinal direction of their profile in longitudinal direction of the carrier profile carrying them, such that each of them engages in profile sections of the carrier profile and/or encompasses such profile sections.

The head elements are form fittingly attached to a ridge element in the area of the upper end of the corresponding ridge element, such that they are each inserted in and/or on contours of the ridge element in longitudinal profile direction of the ridge element and protrude on both sides beyond it in the longitudinal direction of the ridge element, in order to overlap the delimiting edges of the solar modules to be attached.

By this assembly a fastening system can be provided which consists of few parts which can be produced cost-effectively and which makes it possible to also provide a simple and secure fastening of the solar modules on carrier profiles with delimiting edges running transversely to the carrier profiles in difficult ambient conditions.

In a preferred embodiment of the assembly the ridge elements and the carrier profiles are constructively formed in such a way that the ridge elements have to be inserted in and/or on the carrier profile in the longitudinal direction of the profile in order to attach them to the respective carrier profile. Thus, it is not possible to bring them into the intended engagement with the profile contours of the carrier profile from another side than its front side.

By this, a particularly secure fastening of the clamping elements to the carrier profile can be ensured, because a loosening of a ridge element from this carrying carrier profile, in case of installed solar arrays, is possible only after a removal of the solar modules lying on the carrier profile in the direction of the corresponding pushing out or pushing down movement respectively.

In a further preferred embodiment of the assembly the ridge elements and the carrier elements are formed in such a way that the ridge elements can be hung into the carrier profile from above for the fastening to the corresponding carrier profile. Thereby, there are embodiments are also provided in case of which they can additionally be inserted in and/or on the carrier profile in the longitudinal direction of the carrier profile. This embodiment has the advantage that individual ridge elements can be replaced in existing solar arrays without removing solar modules and it is particularly expedient in case very long carrier profiles are used, which could require the removal of many solar modules for the replacement of a ridge element.

In further preferred embodiments of the assembly, the head elements of the clamping elements are formed as simple profile sections or as plate-shaped components, preferably as punched parts made of sheet metal. By this, it is possible to produce these parts particularly cost-effectively.

In yet a further embodiment of the assembly, the clamping elements are formed in such a way that with each clamping element optionally two delimiting edges of two neighbouring solar modules running transversely with respect to the carrier profile or two delimiting edges of two neighbouring solar modules running along the carrier profile can be overlapped, in order to secure against a take-off from the carrier profile in a form fitting way. For this, the head elements don't only protrude on both sides beyond the ridge element in the longitudinal direction of the profile, but also additionally on both sides in a transversal direction with respect to the longitudinal direction of the profile of the ridge element. With this embodiment it is possible to selectively secure delimiting edges of solar modules running along the carrier profile or transversely to it against take-off from the carrier profile with the same clamping elements and without additional components.

In yet a further preferred embodiment of the assembly, the carrier profiles and the clamping elements are formed such that even a single solar module can optionally be attached onto the corresponding carrier profile by each clamping element, in such a way that its head element only overlaps the delimiting edge of this particular solar module. The clamping elements and their fastenings to the carrier profiles have to be formed for this purpose in such a way that they can resist to the bending moments which can arise because of the single sided charge without notable deformations or even damage. By this forming it is possible to use the same clamping elements which are used between the solar modules also for the edge sections, such that one may do without additional special components for this section.

The sections of the head elements protruding beyond the respective ridge element, for overlapping the delimiting edges of the solar modules, have on their undersides adjoining surfaces which serve to adjoin the upper sides of the delimiting edges of the solar modules and thus to hold down the solar modules on the carrier profile. In a preferred embodiment these adjoining surfaces define a plane for each head element.

The head elements and the ridge elements of the clamping elements are each formed, in case of a preferred embodiment variant of this embodiment, in such a way that during the assembly when inserting the head element in and/or on the corresponding ridge element it abuts at the corresponding ridge element in its intended end position. Furthermore, the head elements each have underneath the planes defined by their adjoining surfaces an abutment protruding downwards, which takes effect against the direction of insertion of the head element in and/or on the corresponding ridge element and serves for adjoining the front side of a delimiting edge of a solar module to be attached by this head element, which run transversely with respect to the carrier profile carrying the head element. By this, the head elements are secured to the corresponding ridge element by a solar module held by them in their intended fastening position for installed solar modules.

In another preferred embodiment variant of the embodiment the head elements have each two abutments formed below the plane defined by their adjoining surfaces, which take effect in and against the direction of insertion of the head elements in and/or on the corresponding ridge element and serve for adjoining the front sides of two mutually opposite delimiting edges of two solar modules to be attached by this head element, which run transversely with respect to the carrier profile carrying the head element. These abutments secure the head element in its intended fastening position at the respective ridge element in case of installed solar modules by the solar modules held by this head element.

Depending which installation situation is encountered, the one or the other embodiment variant of this embodiment may be more preferred.

In case of each embodiment variant it is additionally preferred that the head elements are formed in such a way that each abutment can be made ineffective by applying a single bore in the head element at a certain position. For the case that the respective head element doesn't have further noses formed underneath the planes defined by its adjoining surfaces, which is preferred, the head element can then be removed, after applying the bore, for installed solar modules, by pushing down and/or out of the head element from and/or out of the ridge element.

Thereby, a further advantage is that the head elements have each marks showing at which position the bore has to be applied. By this, the targeted appliance of the bores with the aim of removing the abutments is substantially simplified.

In a further embodiment variant of the preferred embodiment of the assembly the form fit connection between the head element and the ridge element is formed exclusively above the plane defined by the adjoining surfaces of the respective head element. By this, the head elements can be formed in such a way, preferably extending exclusively above the plane defined by their adjoining surfaces, except possibly present securing devices which can be kept for the assembly or disassembly respectively, like for example spring noses, that each of them can be inserted in and/or on the ridge elements attached to the carrier profiles, in case of solar modules being arranged in fastening positions, and, optionally after previous removal of a possibly present disassembly securing, can be pushed out and/or down from the respective ridge element in order to enable a simple replacement of individual solar modules.

In yet a further preferred embodiment of the assembly the head elements and the ridge elements are each formed in such a way that the head element snaps with the ridge element in case of the assembly during the insertion in and/or on the corresponding element, this being preferably carried out in such a way that the snap engagement can only be undone by destroying the head element and/or the ridge element. If the head element and the ridge element are executed in a stable way it is possible to create an effective anti-theft protection for the solar modules attached by means of the assembly.

In yet a further preferred embodiment of the assembly the clamping elements are each formed by precisely two components, these being a one-piece ridge element and a one-piece head element inserted in and/or on it. By this, an assembly according to the invention can be formed of a minimum of different components.

In yet a further preferred embodiment of the assembly the carrier profiles and the ridge elements are formed in such a way that the clamping elements can be inserted in and/or on the carrier profiles in multiple different height positions.

In yet a further preferred embodiment of the assembly the head elements and the ridge elements are formed in such a way that the head elements can be inserted in and/or on the ridge elements in multiple different height positions.

By the previously mentioned two embodiments it is possible to use the same components for solar modules of different thickness without requiring additional components for this.

In yet a further preferred embodiment of the assembly one or more separately formed insertion elements per clamping element are provided, these being preferably formed as insertions sheet metal or insertion plates, being form fittingly positioned by the respective ridge element and serving as rest, in one or multiple layers, for the solar modules to be attached by the respective clamping element. By this, the clamping elements can be used for a variety of solar modules with different thickness.

In yet a further preferred embodiment of the assembly the clamping elements are each secured by a targeted plastic deformation of a profile section of the carrier profile and/or of the ridge element against a longitudinal shift along the carrier profile, preferably in both directions. This can for example be carried out in such a way that a profile ridge of the carrier profile, on which the respective ridge element lies, is crimped out beside the ridge element by means of a special tool and therefore forms in a form fitting way an abutment against a shift of the ridge element. By this, no further elements like screws or rivets are needed for securing the clamping elements against shifting along the carrier profiles.

For embodiments of the assembly in case of which the insertion elements mentioned above are used and the clamping elements are each secured against longitudinal shifting along the carrier profile by targeted plastic deformation of a profile section of the carrier profile and/or of the ridge element, it is preferred that, for securing the clamping elements, at least one of the insertion elements, particularly an insertion metal sheet or an insertion metal plate, is present, which is hindered to shift longitudinally along the carrier profile by the plastic deformation of the profile section of the carrier profile and/or the insertion element and makes impossible a longitudinal shift of the clamping element along the carrier profile. This may be particularly advantageous depending on the assembling situation.

In yet a further preferred embodiment of the assembly the carrier profile rows are each formed by multiple carrier profile pieces which are mutually spaced in longitudinal direction. By this, material can be saved and, in case of embodiments for which the ridge elements have to be inserted in and/or on the carrier profiles, the installation effort can be simplified because the ends of the respective carrier profile piece are arranged relatively close to the installation location of the ridge element. Furthermore, there is the advantage that the pushing strain in the fastening points of the respective carrier profile piece or the movement of its fastening points relatively to each other can be limited in narrow boundaries as a result of the unavoidable length change of the latter in the presence of temperature changes, this enabling an easy and reliable fastening of the assembly on a building roof or a façade even without complex fastening solutions.

In yet a further preferred embodiment of the assembly the carrier profiles are each attached in the middle in the profile on the respective installation surface or on a support structure arranged thereon, this promoting its simple and fast assembly.

In yet another preferred embodiment of the assembly the carrier profile rows are arranged parallel or at right angles with respect to the eaves of a building roof carrying them or horizontal or vertical with respect to a building façade respectively, wherein the one or the other variant can be more advantageous depending on the installation situation.

In yet another preferred embodiment of the assembly, in case of which it has the carrier profile rows running parallel with respect to the eaves of a building supporting the assembly, as well as multiple solar modules attached to the assembly on the building roof, preferably removable stop elements are arranged on the underside of the solar modules, each abutting form fittingly at one of the carrier profiles in the direction of the eaves. By this, it is possible to create a reliable protection against slipping for the solar modules in a simple and cost-effective way.

Thereby it is preferred to form the stop elements as removable clips in a single piece, preferably of stainless steel sheet.

A second aspect of the invention is related to a clip for forming a stop element on an outer surface (first outer surface according to the claims) of an even, thin-walled plate-shaped component by attaching the clip in an opening arranged in this outer surface, which is particularly round, rectangular or in the shape of an elongated hole, protruding through the component and ending in a second outer surface according to the claims of the component, which is substantially parallel to the first outer surface. Preferably, the clip is suitable for forming a stop element for both just described embodiments of the assembly according to the first aspect of the invention.

The clip has two arm section connected to each in a springy way by means of a spring section, the free ends of which are spaced from each other in a neutral, meaning a tension-free state and, starting from this state, they can be moved towards each other by overcoming the spring force of the spring section, similarly to the two arms of tweezers.

The arm sections have each one or more contact surfaces (first contact surfaces according to the claims) which are provided for contacting the outer surface of the component in case of an intended fastening of the clip to the component. These first contact surfaces according to the claims define together a contact plane which coincides with the first outer side of the component according to the claims in case of intended assembly of the clip to the component.

The free ends of the arm sections end each in a hook-like fastening section which protrudes beyond the just mentioned contact plane.

The hook-like fastening sections each have a second contact surface according to the claims on the inner side of their hook shape, extending at a distance from the contact plane defined by the contact surfaces according to the claims and serving to contact the second outer surface of the component according to the claims in case of intended fastening of the clips to the component.

The hook-like fastening sections each have on the outer side of their hook shape a first stop surface according to the claims which runs substantially perpendicularly with respect to the contact plane, for forming an abutment inside the opening in the component, against a shift of the respective arm section in an intended abutment direction parallel to the contact plane, in case of an intended fastening of the clip to the component.

Furthermore, the arm sections each have underneath the contact plane a second stop surface according to the claims which is opposed to the first stop surface according to the claims, running substantially perpendicularly to the contact plane, for forming the stop surfaces of the stop element formed by the clip, in case of its intended fastening to the first outer surface of the component according to the claims.

By the clip according to the invention it is possible to form in a simple way at an arbitrary location on an even outer surface of a thin-walled component a stop element which can be removed with one hand and without tools, without having to meet narrow tolerances or without the back side of the component wall needing to be accessible.

In a preferred embodiment of the clip the fastening sections each have on their side facing the spring section, preferably directly following the respective first stop surface according to the claims, a further third contact surface according to the claims, which extends at a distance to the contact plane defined by the first contact surfaces according to the claims, for contacting the second surface of the component according to the claims, in case of intended fastening of the clip to the component. By this, the clip may be locked in the opening in the component in a way that for a removal it first has to be moved in the opening contrary to its abutment direction before its fastening sections can be guided back through the opening to the side of the component formed by the first outer surface according to the claims.

In a further preferred embodiment of the clip it is preferred that the hook-like fastening sections each have on the outer side of their hook shape a rounded, preferably circle-segment-shaped shape. By this it is reached that the fastening sections have a maximum of bending stiffness despite a good insertability into the opening.

In yet a further preferred embodiment of the clip the second contact surface according to the claims and the second stop surface according to the claims directly adjoin each other for each arm section. In this case it is preferred that they are each formed by straight edges of the respective arm section running perpendicularly or almost perpendicularly to each other. In this way unnecessary bending moments and thrust forces in transversal directions with respect to the abutment direction can be avoided.

In yet a further preferred embodiment of the clip the first contact surfaces according to the claims are each formed by straight edges of the arm sections, such that a relatively large contact surface is provided for contacting the first outer surface of the component.

In yet a further preferred embodiment of the clip the arm sections form together with the spring section a single continuous first contact surface according to the claims. By this measure, the contact surface can be maximized, this being preferred, in order to obtain an as low as possible surface pressing at the component.

In yet a further preferred embodiment of the clip the second and/or the third contact surfaces according to the claims are each formed, as far as present, by straight edges of the fastening sections, which run parallel and at a distance from the contact plane. This is preferred in order to also obtain an as low as possible surface pressing on the second outer side of the component according to the claims.

In yet a further preferred embodiment of the clip the spring section is formed by two preferably parallel, mutually spaced spring bridges. By this, it is possible, when the arm sections are sufficiently firm and the spring sections have a desired elasticity, to produce the arm sections and the spring section out of a semi-finished material with a uniform material strength, this being preferred.

In yet a further preferred embodiment of the clip the arm sections of the clip are formed in a mirrored way in order to obtain a symmetric clip assembly.

In further preferred embodiments the clip is formed of one piece, its arm sections are formed as even, planar sections with a constant material strength and/or the clip is formed of a metal sheet material, particularly of stainless steel. All these measures promote a cost-effective manufacture of the clip according to the invention as well as in the last mentioned case also a good durability of the same in the presence of rough climate conditions.

In yet a further preferred embodiment of the clip it is manufactured in one piece by punching a punching piece forming both arm sections and the spring section out of a metal sheet material and subsequent bend in the area of the spring section.

In this case, the shape of the punching piece is preferably chosen in such a way that the contour of the underside of the punching piece is formed substantially as a counter contour with respect to the contour of the upper side of the punching piece, such that the individual punching pieces only leave over little waste material during the punching out of a material web in a fluent sequence. By this, clips according to the invention can be manufactured in an especially cost-effective way in large numbers.

A third aspect of the invention is related to a method for forming a stop element on an even outer surface of a thin-walled component. The method comprises the following method steps:

a) Providing an opening in the outer surface of the component, which protrudes through the wall of the component;

b) providing a clip according to the second aspect of the invention; and

c) arranging the fastening sections of the clip by moving the arm sections towards each other against the spring force of the spring section in such a way in the opening of the component that at least a part of the first contact surfaces according to the claims of the clip contact the outer surfaces of the component (first outer surface according to the claims) and the second contact surfaces according to the claims contact the other side of the wall of the component, in which the opening opens (second outer surface according to the claims).

By the method according to the invention it is possible to form a stop element, which can be installed and removed again without tools, on an even outer surface of a thin-walled component, for example on the underside of a frame forming the delimiting edges of a solar module, out of a hollow profile material or a C-profile material.

### SHORT DESCRIPTION OF THE DRAWINGS

Further embodiments, advantages and applications of the invention result from the dependent claims and the now following description by means of the figures. Thereby it is shown in:

FIG. 1 a perspective top view, obliquely from the top, on an assembly according to the invention on a steep roof of a building;

FIG. 2 a vertical section view in longitudinal direction of the carrier profiles through one of the clamping elements of the assembly of FIG. 1;

FIG. 3 a vertical section, transversal with respect to the longitudinal direction of the carrier profiles through one of the clamping elements of the assembly of FIG. 1;

FIG. 4 a top view on one of the clamping elements of the assembly of FIG. 1;

FIG. 5 a top view on a head element of the clamping elements of the assembly of FIG. 1;

FIG. 6 a vertical section transversal with respect to the longitudinal direction of the carrier profile through a carrier profile and a ridge element attached therein as used in the assembly of FIG. 1;

FIG. 7 a side view on a part of the edge area of the assembly of FIG. 1;

FIG. 8 a view as in FIG. 3 of a preferred embodiment of the assembly of FIG. 1;

FIGS. 9 and 10 views like in FIG. 3 of a second assembly according to the invention;

FIG. 11 a side view of a first clip according to the invention;

FIG. 12 a top view on the clip of FIG. 11;

FIG. 13 the clip of FIGS. 11 and 12 in an intended assembly situation;

FIG. 14 a top view on a punching part for forming a clip of FIGS. 11 to 13;

FIG. 15 a top view on an intermediary product during the production of the punching part of FIG. 14;

FIG. 16 a side view of a second clip according to the invention;

FIG. 17 the clip of FIG. 16 in an intended assembly situation;

FIG. 18 a top view on a punching part for forming the clip of FIGS. 16 and 17;

FIG. 19 a side view of a third clip according to the invention; and

FIG. 20 a top view on the clip of FIG. 19.

### WAYS OF CARRYING OUT THE INVENTION

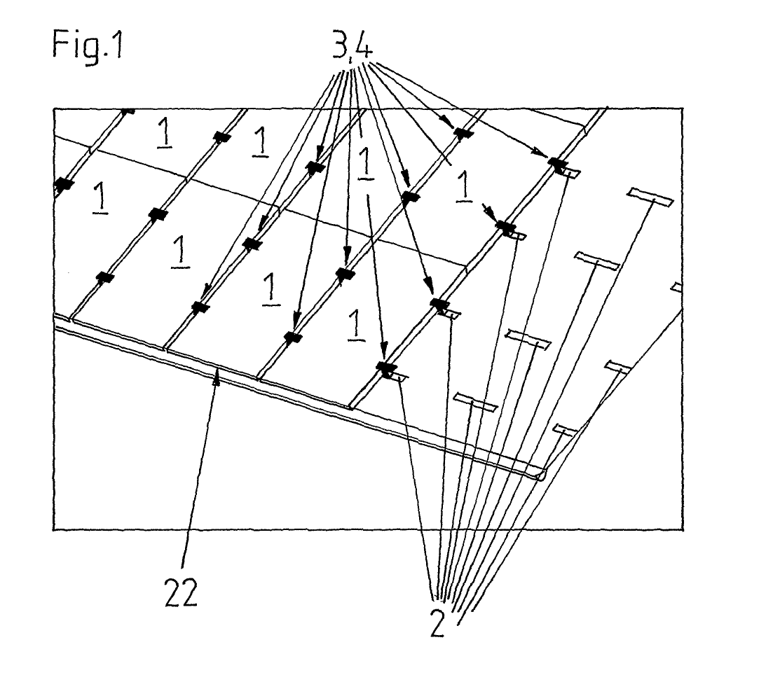

A first assembly according to the invention for the fastening of a plurality of solar modules for forming a solar array is shown in FIG. 1 during its assembly on a steep roof of a building in a perspective top view. As one can see particularly in the right area of the shown roof, where the assembly is not yet finished, it comprises multiple carrier profile pieces 2 which are arranged spacedly with respect to each other in rows which are parallel to the eaves 22 of the roof. Each carrier profile piece 2 carries a clamping element 3, 4 by means of which two neighbouring solar modules 1 are attached on the carrier profile piece 2 carrying the clamping element 3, 4, in a manner that the delimiting edges of both solar modules 2, which oppose each other and run transversely with respect to the carrier profile piece 2 and adjoin the clamping element 3, 4 on both sides, are overlapped by the clamping element 3, 4 and are thereby form fittingly secured against a take-off from the carrier profile piece 2.

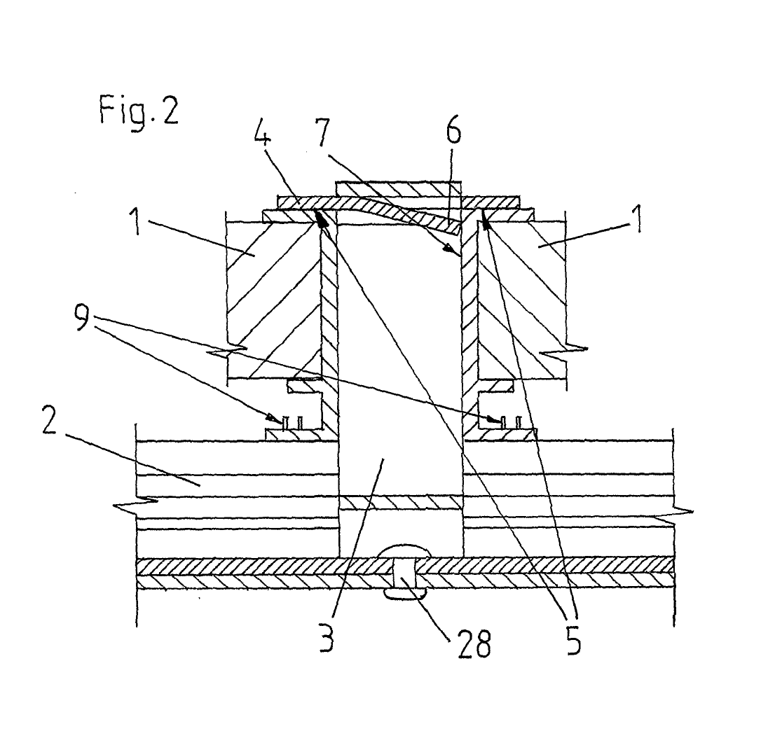

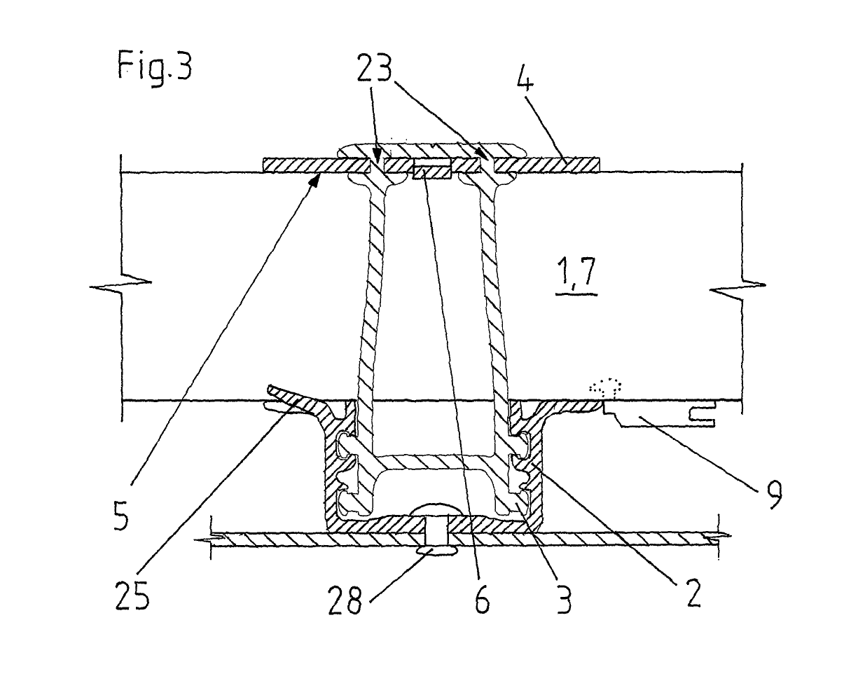

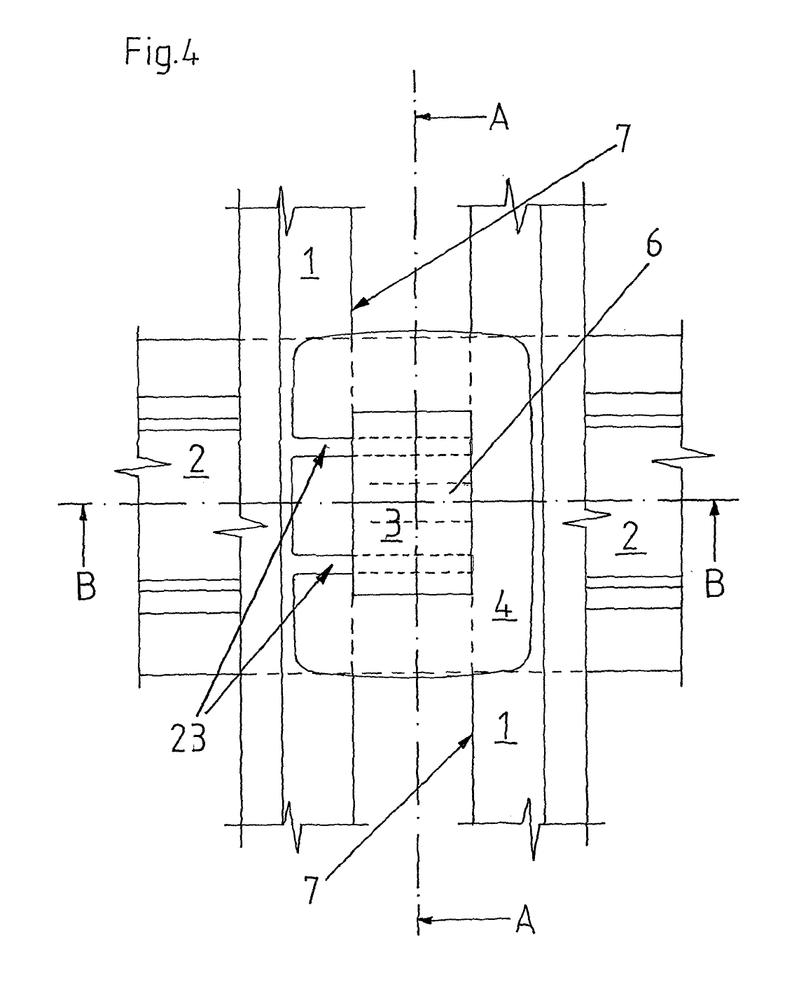

As can be seen by looking at FIGS. 2, 3 and 4, which show a vertical section in longitudinal direction of the carrier profile pieces 2 through one of the clamping elements 3, 4 (FIG. 2), transversely with respect to the longitudinal direction of the carrier profile pieces 2 through one of the clamping elements 3, (FIG. 3) as well as a top view on one of the clamping elements 3, 4 (FIG. 4), the clamping elements 3, 4 consist each of a ridge element 3 which is arranged between the delimiting edges of the solar modules 2 and of a head element 4 for overlapping the delimiting edges of the solar modules 2 which is formed separately from the ridge element.

The ridge elements 3 are formed as profile sections and are each oriented with their longitudinal profile direction in a longitudinal direction of the respective carrier profile piece 2 carrying them. The ridge elements 3 are each attached at their bottom ends in a form fitting way to the carrier profile piece 2, in a manner that they engage with profile contour formed by them in profile sections of the carrier profile piece 2. Thereby, the ridge elements 3 and the carrier profile pieces 2 are formed in such a way that the ridge elements 3 have to be inserted into the respective carrier profile piece 2 in the longitudinal profile direction of the carrier profile piece 2 in order to attach them to it.

The head elements 4 are attached in a form fitting way to the ridge element 3 in the area of the upper end of this ridge element 3 carrying them, in a manner that they each are inserted into profile contours of the ridge element 3 in the longitudinal profile direction of the ridge element 3 and protrude on both sides beyond the ridge element 3 in the longitudinal profile direction of the ridge element 3, in order to overlap the delimiting edges of the solar modules 1 to be fastened.

The carrier profile pieces 2 are each attached in the middle of the profile to the upper side of the roof formed by metal sheet by means of multiple rivets 28.

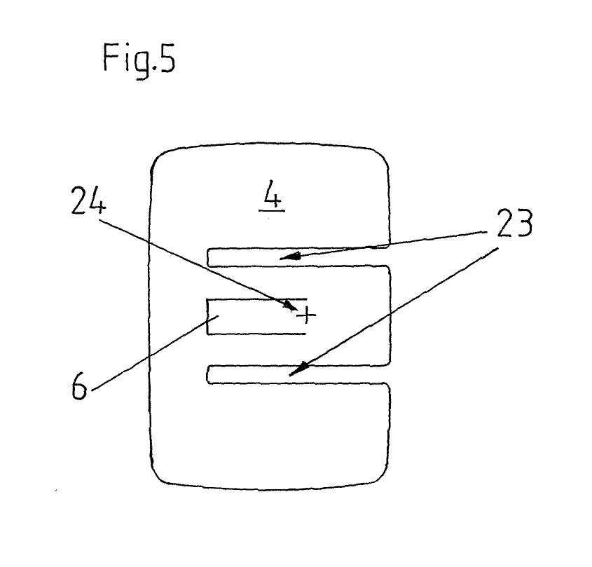

As can be seen in combination with FIG. 5 which shows a top view on one of the head elements 4, the head elements 4 are formed as plate-shaped punched parts made of aluminium sheet material and are dimensioned in such a way that two delimiting edges running along each carrier profile piece 2 of two neighbouring solar modules can also optionally be overlapped by each clamping element 3, 4, in order to secure in a form fitting way against a take-off from the carrier profile piece 2.

The areas of the head elements 4 which protrude beyond the ridge element 3 carrying them in order to overlap the delimiting edges of the solar modules 1 have on their underside adjoining surfaces 5 which adjoin the upper sides of the delimiting edges of the solar modules 1 and consequently hold these on the carrier profile pieces 2. These adjoining surfaces 5 define a plane for each head element 4.

As can particularly be seen in FIGS. 3 to 5, the head elements 4 have each two slits 23 arranged and formed in such a way that the head element 4 abuts with the end surfaces of the slits 23 to the front side of the ridge element 3 during the assembly by insertion into the respective ridge element 3 in its intended end position.

Underneath the plane defined by its adjoining surfaces 5, each head element 4 has an abutment 6 protruding downwards and acting against the insertion direction into the respective ridge element 3, being formed as a punched sheet metal nose 6 in one piece with the head element 4 and abutting at the front side 7 of a delimiting edge of a solar module 1 attached by this head element 4 and running transversely with respect to the corresponding carrier profile piece 2. By this, the head elements 4 are secured in their intended position in a direction against their inserting direction in case of installed solar modules 1.

As can be seen in FIG. 5, the head elements 4 have a mark 24 on their upper side. This mark 24 describes at which position a bore with a diameter corresponding to the width of the sheet metal nose 6 has to be executed into the head element 4, for the case that the abutment formed by the sheet metal nose 6 shall be made ineffective. Because the head elements 4 extend each exclusively above the plane defined by their adjoining surfaces 5, they can be removed from the respective ridge element 3 carrying them, in case of installed solar modules 1, by a shift against their insertion direction, after the abutment 6 has been made ineffective by executing the bore. By this it is possible to replace individual solar modules 1 in a simple and fast way by temporarily removing the respective head element 4 holding the solar module 1.

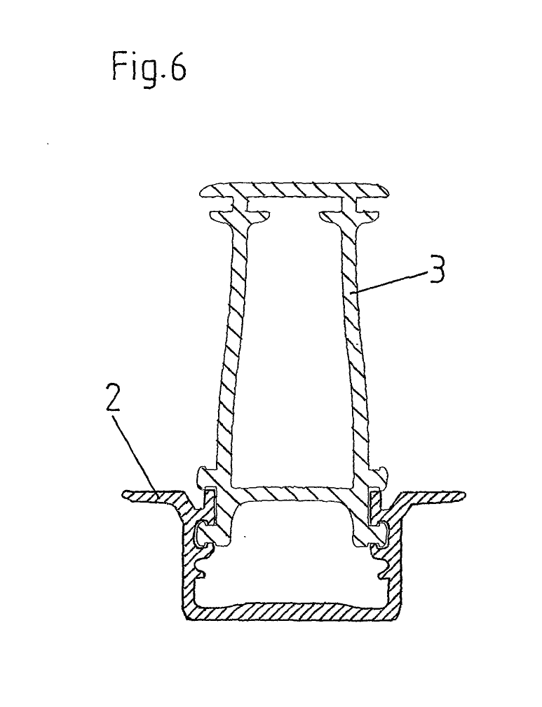

As can further be seen from FIG. 3 together with FIG. 6, the carrier profile pieces 2 and the ridge elements 3 of the clamping elements 3, 4 are formed in such a way that the clamping elements 3, 4 can be inserted into the carrier profile pieces 2 and/or on them in different height positions. Accordingly, the shown carrier profile pieces 2 and the clamping elements 3, 4 are basically suitable for two different solar module thicknesses.

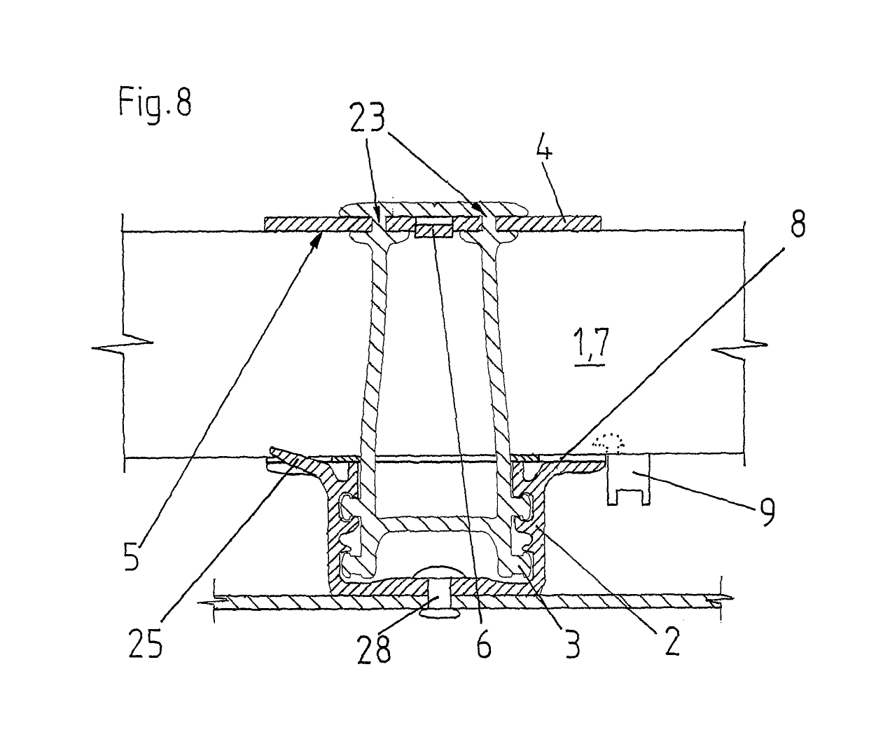

As can be seen in FIG. 8, which shows a view as in FIG. 3 of a preferred embodiment of the assembly, it is additionally also provided that one or more separately formed insertion elements 8 per clamping element 3, 4 are used between the solar modules 1 and the carrier profile pieces 2 being formed as insertion sheet and being positioned in a form fitting way by the respective ridge element 3 in order to make it possible to adjust the assembly according to the invention to different solar module thicknesses.

As can further be seen in FIGS. 3 and 8, the solar modules 1 are each form fittingly secured against a shift along the respective carrier profile piece 2 by a targeted plastic deformation 25 of a profile section of the carrier profile piece 2 in the area of the front surfaces 7 of their delimiting edges. For this, the insertion sheets 8 have corresponding cut-outs in the embodiment according to FIG. 8, inside of which the plastic deformation 25 of the profile section of the carrier profile piece 2 is done. By this, also the insert plate 8 is at the same time form fittingly hindered, by the plastic deformation 25, to shift longitudinally along the carrier profile piece 2 and in the end also the clamping element 3, 4, because it encloses the ridge element 3.

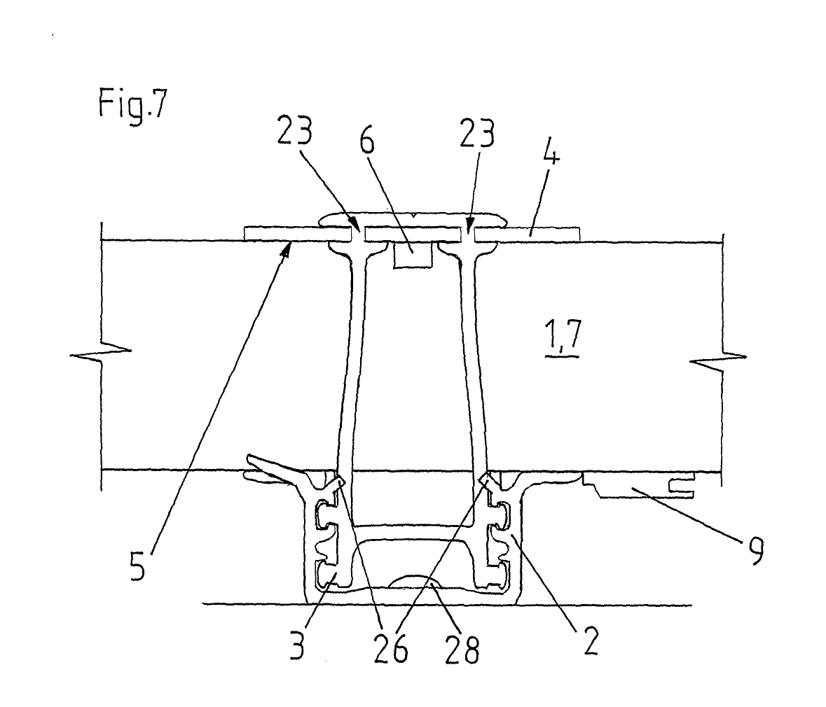

FIG. 7 shows a side view on a part of the edge area of the assembly of FIG. 1, precisely on the front side of a carrier profile piece 2 with the last clamping element 3, 4 arranged therein. As can be seen, the ridge element 3 of the clamping element 3, 4, the head element 4 of which overlaps a solar module 1 only on one side because of the positioning at the edge of the solar array and is therefore attached on the carrier profile piece 2, is form fittingly secured against a drive out of its profile contour by a further plastic deformation 26 of profile sections of the carrier profile piece 2 at the end of the latter.

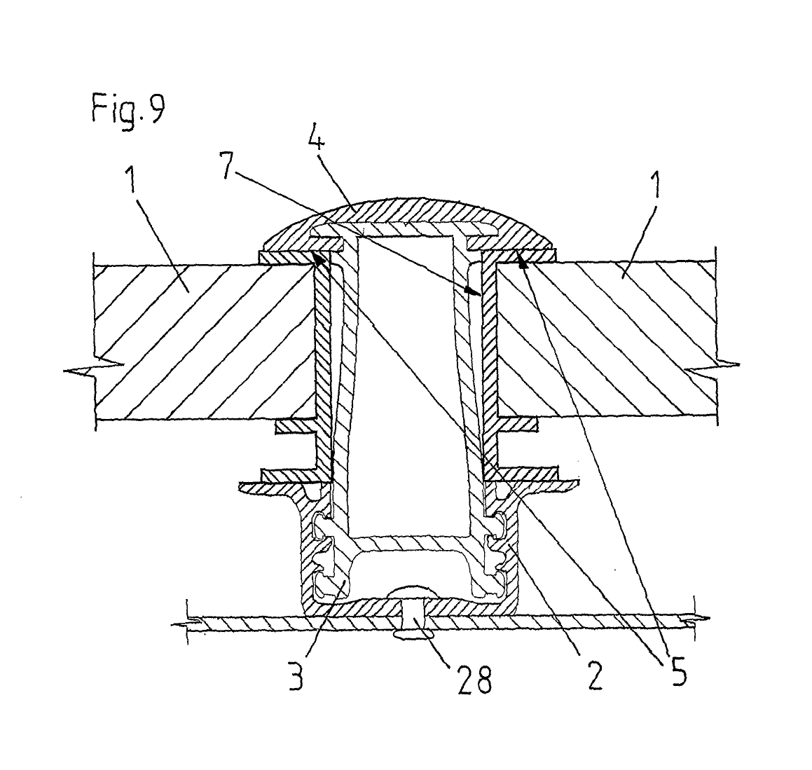

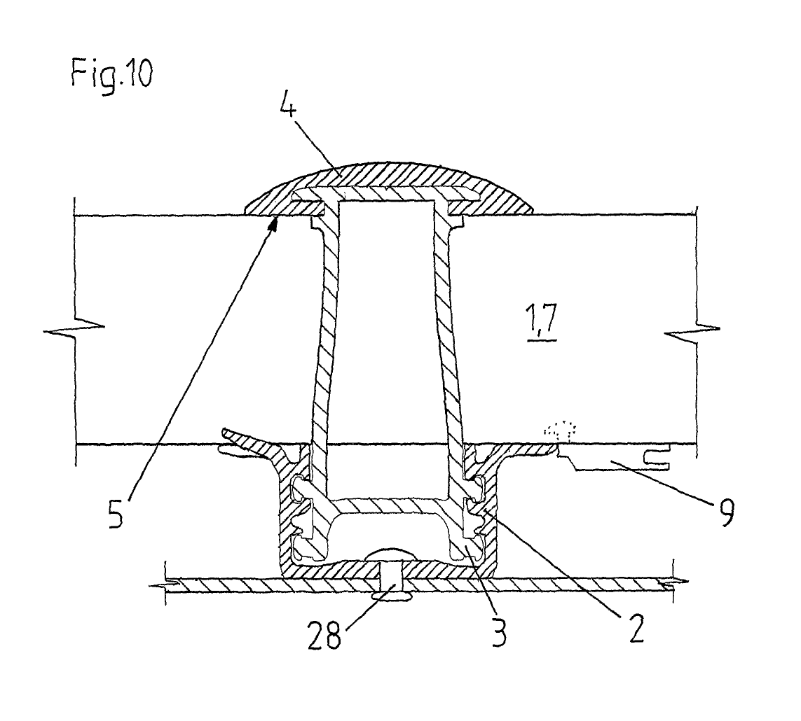

FIGS. 9 and 10 show views as FIG. 3 of a second assembly according to the invention, wherein in FIG. 10 and also in FIG. 3 the overlapped delimiting edges of the solar modules 1 run transversely to the carrier profile parts 2, whereas they run along them in FIG. 9. As can be seen, the main difference between the first assembly according to the invention according to FIGS. 1 to 8 is that the head element 4 is here formed by a simple profile section which, in its intended position, protrudes beyond the ridge element 3 in longitudinal profile direction of the ridge element 3 carrying it as well as transversely to it and thus makes optionally possible the fastening situation shown in FIG. 9 or the one shown in FIG. 10.

As can be seen in FIGS. 3, 7, 8 and 10, the solar modules 1 have, in assembly situations in which they are attached with their delimiting edges running transversely to the carrier profile pieces 2 on the carrier profile pieces 2 running parallel to the eaves 22 of the building roof, on their underside stop elements 9 which form fittingly abut at the respective carrier profile piece 2 in the direction towards the eaves and thereby serve as form fitting anti-slipping-securing for the respective solar module 1.

The stop elements 9 are formed in this case by one-piece clips 9 made of stainless steel sheet, which can be assembled and disassembled with one hand without tools.

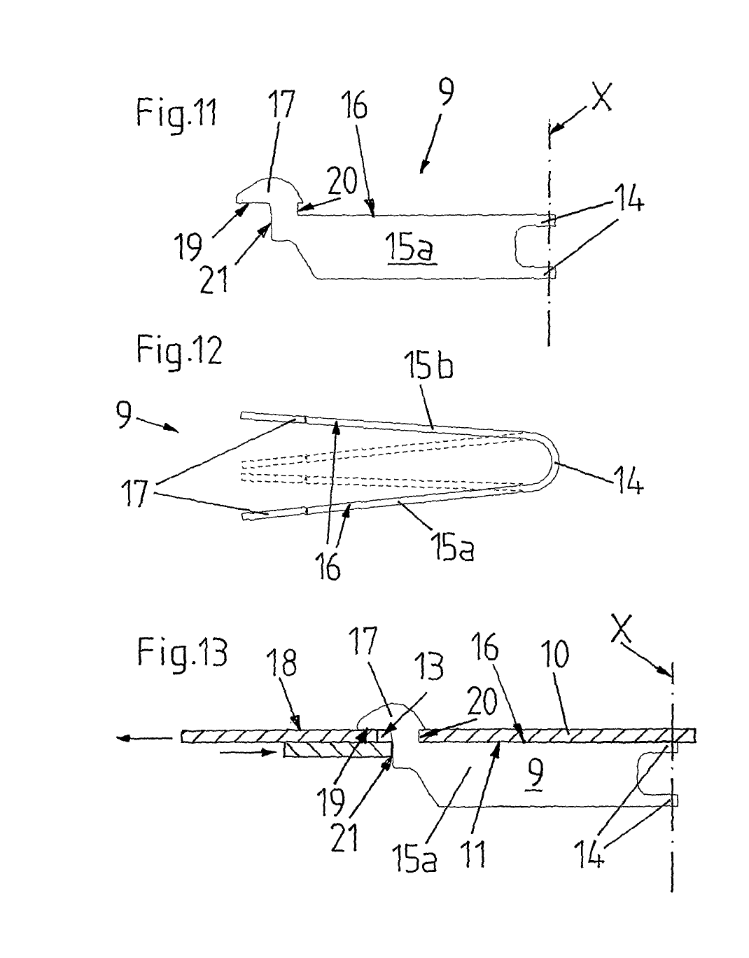

FIGS. 11 to 13 show a first embodiment according to the invention of a clip 9, as it is used in the assemblies of FIGS. 3 and 7, once in a side view (FIG. 11), once in a top view (FIG. 12) and once in another intended assembly situation than in FIGS. 3 and 7 (FIG. 13).

As one can see in FIG. 13, the clip 9 is suitable for forming a stop element on an outer surface 11 of an even, thin-walled, plate-shaped component 10 by attaching the clip in an opening 13, which is particularly round, rectangular or in the shape of an elongated hole, arranged in this outer surface 11, protruding through the component 10 and ending in a second outer surface 18 of the component 10, which is substantially parallel to the first outer surface 11.

The clip 9 is formed in one piece out of a punched part of stainless steel with uniform material strength and has two arm sections 15a, 15b which are connected to each other in a springy way by a spring section 14, their free ends being spaced relatively to each other in a neutral, thus tension-free state, and which can be moved towards each other by overcoming the spring force of the spring section 14, this being indicated in FIG. 12 by the pointed lines. The spring section 14 is formed by two parallel spring ridges.

The arm sections 15a, 15b form each on their upper side first contact surfaces 16 which form together with the upper side of the spring section 14 a single continuous straight first contact surface 16 for contacting the outer surface 11 of the component 10, to which a stop element shall be formed by the clip 9. These first contact surfaces 16 of the arm sections 15a, 15b or the continuous contact surface 16 formed together with the spring section 14 respectively define a contact plane.

As one can further see, the free ends of the arm sections 15a, 15b end each in a hook-like fastening section 17 which protrudes beyond the contact plane.

On the inner side of their hook shape, the hook-like fastening sections 17 form each a second contact surface 19 which extends at a distance parallel to the contact plane and serves to contact the second outer surface 18 of the component 10.

On the outer side of their hook shape, the hook-like fastening sections 17 form each a first stop surface 20 running substantially perpendicularly with respect to the contact plane, in order to form an abutment in the opening 13 against a shifting of the respective arm section 15a, 15b in a direction parallel to the contact surface.

Below the contact surface the arm sections 15a, 15b have each a second stop surface 21 which is opposed from the first stop surface 20 and runs substantially perpendicularly with respect to the contact plane, serving for forming the stop surfaces of the stop element formed by the clip 9 on the first outer surface 11 of the component 10. The fastening sections 17 have each a third contact surface 22 on their side facing the spring section 14 directly following the respective first stop surface 20, extending parallel at a distance from the contact plane and, like the second contact surface 19, serves to contact the second outer surface 18 of the component 10. On the outer side of their hook shape, the hook-like fastening sections 17 additionally have each a rounded, particularly circle-segment-shaped shape.

As one can see, the second contact surfaces 19 and the second stop surfaces 21 directly adjoin each other and are each formed by straight edges of the arm sections 15a, 15b running vertically with respect to each other.

FIG. 14 shows a top view on the punched part out of which the clip 9 was manufactured by bending in the area of its spring section 14. As can be seen, both arm sections 15a, 15b are formed in a mirrored way.

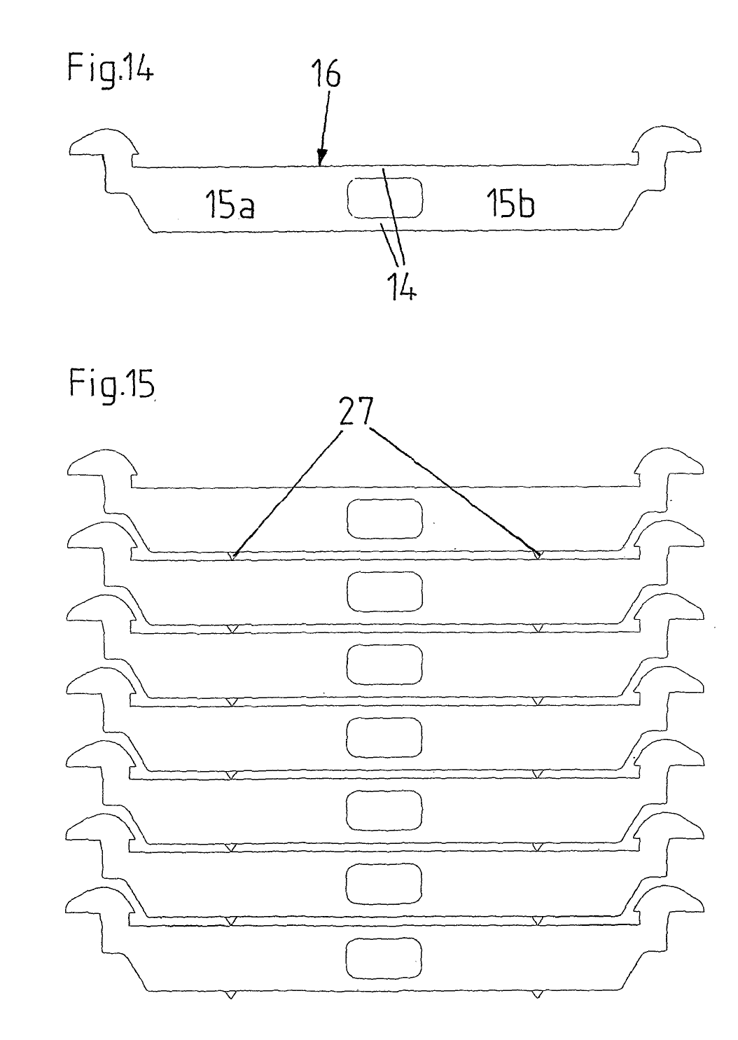

FIG. 15 shows a top view on an intermediary product during the production of the punched part of FIG. 14, out of which the punched parts according to FIG. 14 are executed by separating the partial elements which are only interconnected by two thin ridges 27. As it is evident here, the shape of the partial elements forming the individual punched parts according to FIG. 14 after separation is chosen in such a way that the contour of the underside of the individual punched part is formed substantially as counter contour with respect to the contour of the upper side of the punched part, such that almost no waste material is produced during the serial punching. This can be seen from the very tiny gaps between the partial elements.

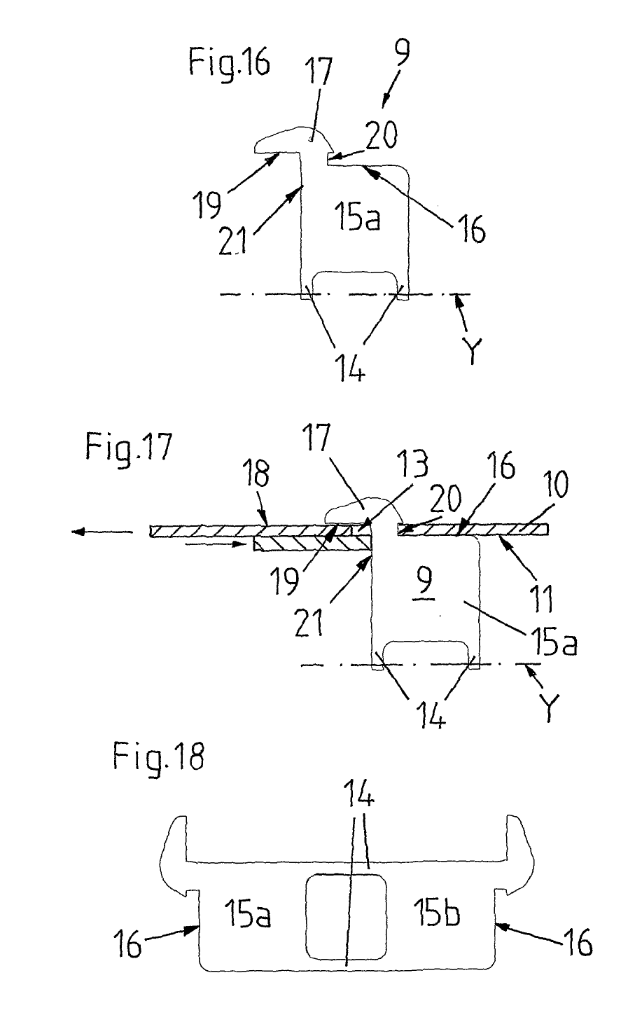

FIGS. 16 to 18 show views like FIGS. 11, 13 and 14 of a second clip 9 according to the invention, as it is used in the assembly in FIG. 8, or the punched part used to form it respectively, wherein the only central difference between both embodiments consists in that in case of the first embodiment the arm sections 15a, 15b are connected to each other in a springy way by the spring section 14 such that they can be pivoted towards each other, by overcoming the spring force of the spring section 14, about a pivot axis X which is perpendicular to the contact plane, and contrary to this in case of the second embodiment about a pivot axis Y running parallel with respect to the contact plane.

In order to form with the clips 9, as shown in FIGS. 13 and 17, a stop element at an even outer surface of a thin-walled component, the fastening sections 17 of the respective clip are arranged inside the opening 13 of the component 10 in such a way, by moving the arm sections 15a, 15b towards each other against the spring force of the spring section 14, that the first contact surface 16 contacts the outer side 11 of the component 10 and the second contact surfaces 19 contact the side 18 of the wall of the component 10 which is opposed to the first outer side 11.

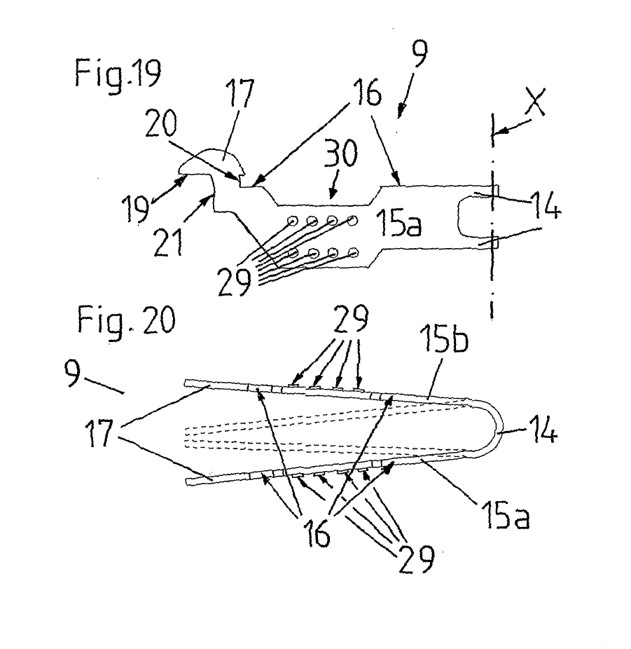

FIGS. 19 and 20 show a third embodiment of a clip 9 according to the invention, once in a side view (FIG. 19) and once in a top view (FIG. 20). This clip 9 differs from the clip shown in FIGS. 11 to 13 substantially in that it has embossments 29 protruding towards the outside in the areas where it is typically gripped between forefinger and thumb for the installation or the disassembly respectively, by this increasing its grip. Additionally, this area is placed deeper here than the one in the assembly of FIGS. 11 to 13, such that the handling of the clip 9 during the installation and assembly is further enhanced because in the intended installed state this area of the clip 9 protrudes from the surface 11 of the component, on which it forms an abutment. A further difference to the clip shown in FIGS. 11 to 13 consists in that here the arm sections 15a, 15b have each on their upper side a cavity 30 such that they each form two separate contact surfaces 16. By this cavity 30, the upper side of the punched part on which the clip 9 is manufactured by bending in the area of the spring sections 14 has substantially the counter contour with respect to the contour of its underside, such that the individual punched parts leave over only little waste material during the punching in a row out of a material web, as shown for the punched parts of the embodiment according to FIGS. 11 to 13.

While preferred embodiments of the invention are described in the present patent application, it is clearly noted that the invention is not limited to these embodiments but can also be carried out in different ways within the scope of the following claims.

1. Assembly for fastening a plurality of solar modules for assembling a solar array on a building roof or a building façade, comprising a plurality of carrier profiles which are arranged in rows spaced from each other and each carry one or more clamping elements for fastening the solar modules on the carrier profiles,
wherein the clamping elements are formed in such a way that with each clamping element two neighbouring solar modules can be fastened on the carrier profile supporting the clamping element in such a way that the delimiting edges of both solar modules facing each other and running transversely to the carrier profile, which adjoin the clamping element on both sides, are overlapped by the clamping element and are therefore secured in a form fitting way against take-off from the carrier profile,
wherein the clamping elements comprise each a ridge element for an assembly between the delimiting edges of the solar modules and a head element formed separately from the ridge element for overlapping the delimiting edges of the solar modules,
wherein the ridge elements are formed as profile sections and are form fittingly attached to the corresponding carrier profile at their lower ends, each being oriented with its longitudinal profile direction in longitudinal direction of the carrier profile supporting them, in such a way that each of them engages in profile sections of the carrier profile with profile contours formed by these and/or encompasses profile sections of the carrier profile,
wherein the head elements are form fittingly attached to this ridge element in the area of the upper end of the corresponding ridge element, in such a way that they are each inserted in and/or on contours of the ridge element in longitudinal profile direction of the ridge element and protrude on both sides beyond the ridge element in the longitudinal direction of the ridge element, in order to overlap the delimiting edges of the solar modules to be fastened.

2. Assembly according to claim 1, wherein the ridge elements and the carrier profiles are formed in such a way that the ridge elements have to be inserted in and/or on the carrier profile for a fastening in the longitudinal profile direction to the respective carrier profile.

3. Assembly according to claim 1, wherein the ridge elements and the carrier profiles are formed in such a way that the ridge elements can be hung into the carrier profile from above for fastening to the respective carrier profile.

4. Assembly according to claim 1, wherein the head elements of the clamping elements are formed as simple profile sections.

5. Assembly according to claim 1, wherein the head elements of the clamping elements are formed as plate-shaped components, particularly as punched parts made of sheet metal.

6. Assembly according to claim 1, wherein the clamping elements are formed in such a way that with each clamping element optionally two delimiting edges of two neighbouring solar modules running transversely with respect to the carrier profile or two delimiting edges of two neighbouring solar modules running along the carrier profile can be overlapped, for securing in a form fitting way against a take-off from the carrier profile.

7. Assembly according to claim 1, wherein the carrier profiles and the clamping elements are formed in such a way that even a single solar module can be fastened onto the respective carrier profile by each clamping element, in such a way that its head element only overlaps the delimiting edge of this particular solar module.

8. Assembly according to claim 1, wherein the sections of the head elements protruding beyond the respective ridge element, for overlapping the delimiting edges of the solar modules, have on their undersides adjoining surfaces serving to adjoin the upper sides of the delimiting edges of the solar modules, which adjoining surfaces each define a plane, wherein the head elements and the ridge elements of the clamping elements are each formed in such a way that during the assembly, when inserting the respective head element in and/or on the corresponding ridge element, the head element abuts at the ridge element in its intended end position, and wherein the respective head element furthermore has underneath the plane defined by its adjoining surfaces an abutment protruding downwards and which takes effect against its direction of insertion in and/or on, for adjoining the front side of a delimiting edge of a solar module to be attached with this head element, running transversely with respect to the carrier profile carrying the head element.

9. Assembly according to claim 1, wherein the sections of the head elements protruding beyond the respective ridge element, for overlapping the delimiting edges of the solar modules, have on their undersides adjoining surfaces serving to adjoin the upper sides of the delimiting edges of the solar modules, which adjoining surfaces each define a plane, wherein the head elements have each two abutments formed below the plane defined by their adjoining surfaces and taking effect in and against the direction of insertion in and/or on the head element, for adjoining the front sides of two delimiting edges of two solar modules to be attached with this head element facing each other and running transversely with respect to the carrier profile carrying the head element.

10. Assembly according to claim 1, wherein the head elements are formed in such a way that each one of the abutments can be made ineffective by applying a single bore at a certain position in the head element.

11. Assembly according to claim 10, wherein the head elements each have marks showing at which position the respective bore has to be applied.

12. Assembly according to claim 1, wherein the sections of the head elements protruding beyond the respective ridge element, for overlapping the delimiting edges of the solar modules, have on their undersides adjoining surfaces for adjoining the upper sides of the delimiting edges of the solar modules, which adjoining surfaces each define a plane and wherein the head elements are each attached in a form fitting way exclusively above this plane to the corresponding ridge element.

13. Assembly according to claim 12, wherein the head elements each extend exclusively above the plane defined by their adjoining surfaces.

14. Assembly according to claim 1, wherein the head elements and the ridge elements of the clamping elements are each formed in such a way that the head element snaps with the ridge element in case of the assembly during the insertion in and/or on the corresponding head element, and particularly wherein the snap engagement is done in such a way that it can only be undone by destroying the head element and/or the ridge element.

15. Assembly according to claim 1, wherein the clamping elements are each formed by precisely two components, a one-piece ridge element and a one-piece head element inserted into it.

16. Assembly according to claim 1, wherein the carrier profiles and the ridge elements of the clamping elements are formed in such a way that the clamping elements can be inserted in and/or on the carrier profiles in a plurality of different height positions.

17. Assembly according to claim 1, wherein the head elements and the ridge elements of the clamping elements are formed in such a way that the head elements can be inserted in and/or on the ridge elements in a plurality of different height positions.

18. Assembly according to claim 1, wherein the solar modules are each form fittingly secured against a longitudinal shift along the carrier profile by a targeted plastic deformation in the area of the front surfaces of their delimiting edges.

19. Assembly according to claim 1, wherein one or more separately formed insertion elements per clamping element are provided, which are particularly formed as insertion sheet metal or insertion plates, wherein the insertion elements are form fittingly positioned by the respective ridge element and serve as rest, in one or multiple layers, for the solar modules to be fastened, in order for a use of the same clamping elements for solar modules of different thickness.

20. Assembly according to claim 1, wherein the clamping elements are each secured by a targeted plastic deformation of a profile section of the carrier profile and/or of the ridge element against a longitudinal shift along the carrier profile, particularly in both longitudinal directions.

21. Assembly according to claim 19, wherein the clamping elements are each secured by a targeted plastic deformation of a profile section of the carrier profile and/or of the ridge element against a longitudinal shift along the carrier profile, particularly in both longitudinal directions and wherein for the securing of the clamping elements at least one of the insertion elements is present, being hindered to shift longitudinally along the carrier profile by the plastic deformation of the profile section of the carrier profile and/or of the insertion element and makes impossible a longitudinal shift of the clamping element along the carrier profile.

22. Assembly according to claim 1, wherein the carrier profile rows are each formed by multiple carrier profile pieces which are mutually spaced in longitudinal direction.

23. Assembly according to claim 1, wherein the carrier profiles are each attached in the middle in the profile on the installation surface or on a subordinate construction arranged on the installation surface.

24. Assembly according to claim 1, wherein the carrier profile rows run parallel or at right angles with respect to the eaves (22) of a building roof carrying it.

25. Assembly according to claim 1 with carrier profile rows running parallel with respect to the eaves of a building carrying the assembly, comprising multiple solar modules attached on the building roof by means of the assembly, wherein particularly removable stop elements arranged on the underside of the solar modules are provided, abutting form fittingly at one of the carrier profiles in the direction of the eaves and thereby serving as an anti-slipping protection for the respective solar module.

26. Assembly according to claim 25, wherein the removable stop elements are formed as clips in one piece, particularly made of stainless steel sheet.

27. Clip for forming a stop element on a first outer surface of an even, thin-walled, plate-shaped component by attaching it in an opening arranged in this outer surface, which is particularly round, rectangular or in the shape of an elongated hole, protruding through the component and ending in a second outer surface of the component, which is substantially parallel to the first outer surface, particularly for forming the stop element in one of the assemblies according to claim 25, comprising two arm sections which are connected to each other in a springy way by means of a spring section, the free ends of which are spaced from each other in a neutral state and are movable towards each other by overcoming the spring force of the spring section,
wherein the arm sections have each one or more first contact surfaces for contacting the outer surface of the component in case of an intended fastening of the clip to the component, and wherein the first contact surfaces define together a contact plane,
wherein the free ends of the arm sections end each in a hook-like fastening section which protrudes beyond the contact plane,
wherein the hook-like fastening sections each have a second contact surface on the inner side of their hook shape, extending at a distance from the contact plane defined by the contact surfaces, for contacting the second outer surface of the component in case of intended fastening of the clip to the component,
wherein the hook-like fastening sections each have a first stop surface on the outer side of their hook shape, running substantially perpendicularly to the contact plane, for forming an abutment in the opening against a shift of the respective arm section in a direction parallel to the contact plane, in case of an intended fastening of the clip to the component,
and wherein the arm sections each have underneath the contact plane a second stop surface which is opposed to the first stop surface, running substantially perpendicularly to the contact plane, for forming the stop surfaces of the stop element formed by the clip, in case of its intended fastening to the first outer surface of the component.

28. Clip according to claim 27, wherein the fastening sections each have on their side facing the spring section, particularly directly following the respective first stop surface, a third contact surface extending at a distance to the contact plane defined by the first contact surfaces, for contacting the second outer surface of the component, in case of intended fastening of the clip to the component.

29. Clip according to claim 27, wherein the hook-like fastening sections each have on the outer side of their hook shape a rounded, particularly circle-segment-shaped, shape.

30. Clip according to claim 27, wherein the second contact surfaces and the second stop surfaces each directly adjoin each other, and particularly wherein they are each formed by straight edges of the respective arm section running perpendicularly or almost perpendicularly with respect to each other.

31. Clip according to claim 27, wherein the first contact surfaces are each formed by straight edges of the arm sections.

32. Clip according to claim 27, wherein the arm sections form together with the spring section a single continuous first contact surface.

33. Clip according to claim 27, wherein the second and/or the third contact surfaces, as far as present, are formed by straight edges of the fastening sections, running parallel at a distance from the contact plane.

34. Clip according to claim 27, wherein the spring section is formed by two preferably parallel, mutually spaced spring bridges.

35. Clip according to claim 27, wherein the arm sections are formed in a mirrored way.

36. Clip according to claim 27, wherein the clip is formed in one piece.

37. Clip according to claim 27, wherein the arm sections are formed as even, planar sections with constant material strength.

38. Clip according to claim 27, wherein the clip is formed by a sheet metal material, particularly by stainless steel.

39. Clip according to claim 38, wherein the clip is manufactured in one piece by punching a punching part forming both arm sections and the spring section out of a metal sheet material and subsequent bending in the area of the spring section.

40. Clip according to claim 39, wherein the shape of the punching part is such that the contour of the underside of the punching part is formed substantially as a counter contour with respect to the contour of the upper side of the punching part.

41. Method for forming a stop element on an even outer surface of a thin-walled component, comprising the steps:
a) providing an opening in the outer surface of the component, which protrudes through the wall of the component;
b) providing a clip according to claim 27; and
c) arranging the fastening sections of the clip, by moving the arm sections towards each other against the spring force of the spring section in such a way into the opening that at least a part of the first contact surfaces contact the outer surface of the component and the second contact surfaces contact the side of the wall of the component which faces the first outer surface.
